(19) United States
(12) Patent Application Publication
(10) Pub. No.: US 2014/0273290 A1
(43) Pub. Date: Sep. 18, 2014

(54) SOLVENT ANNEAL PROCESSING FOR DIRECTED-SELF ASSEMBLY APPLICATIONS

(71) Applicant: TOKYO ELECTRON LIMITED, Tokyo (JP)

(72) Inventor: Mark H. Somervell, Austin, TX (US)

(73) Assignee: TOKYO ELECTRON LIMITED, Tokyo (JP)

(21) Appl. No.: 13/843,122

(22) Filed: Mar. 15, 2013

(51) Int. Cl. H01L 21/66; H01L 21/324

(52) U.S. Cl. CPC H01L 22/12; H01L 21/324
USPC 438/5; 34/90

(57) ABSTRACT

A method and apparatus for solvent annealing a layered substrate including a layer of a block copolymer are provided. The method includes (a) introducing an annealing gas into a processing chamber; (b) maintaining the annealing gas in the processing chamber for a first time period; (c) removing the annealing gas from the processing chamber; and (d) repeating steps (a)-(c) a plurality of times in order induce the block copolymer to undergo cyclic self-assembly. The apparatus includes a processing chamber comprising a process space; a substrate support in the process space; an annealing gas supply and a purge gas supply, both in fluid communication with the process space; a heating element positioned within the processing chamber; an exhaust port in the processing chamber; and a sequencing device programmed to control the annealing gas supply, the heating element, the isolation valve of the exhaust port, and the purge gas supply.

### FIELD OF THE INVENTION

The present invention relates generally to methods of fabricating semiconductor devices and, more specifically, to apparatus and methods of fabricating semiconductor devices using directed self-assembly processes.

### BACKGROUND OF THE INVENTION

Directed self-assembly (“DSA”) processes use block copolymers to form lithographic structures. There are a host of different integrations for DSA (e.g., chemi-epitaxy, grapho-epitaxy, hole shrink, etc.), but in all cases the technique depends on the rearrangement of the block copolymer from a random, unordered state to a structured, ordered state that is useful for subsequent lithography. The morphology of the ordered state is variable and depends on a number of factors, including the relative molecular weight ratios of the block polymers. Common morphologies include line-space and cylindrical, although other structures may also be used. For example, other ordered morphologies include spherical, lamellar, bicontinuous gyroid, or miktoarm star microdomains.

Conventional thermal annealing of most block copolymers (e.g., PS-b-PVP, etc.) in air or vacuum will typically result in one block preferentially wetting the air vapor interface, which makes it more difficult to form the perpendicular oriented microdomains desirable for nanolithography. Moreover, many high χ block copolymers possess order-disorder temperatures well above the block copolymers thermal degradation temperature making thermal annealing less practical. A variant of thermal annealing, called zone annealing, can provide rapid self-assembly (e.g., on the order of minutes) but is generally only effective for a small number of block copolymers (e.g., PS-b-PMMA, PS-b-PLA) with polymer domains that equally wet the air vapor interface. Conventional solvent annealing process have been demonstrated to mitigate preferential wetting of one block, and therefore favor producing a perpendicular orientation of the self-assembled domains to the substrate. However, traditional solvent vapor-assisted annealing is generally a very slow process, typically on the order of days, and can require large volumes of the solvent. A typical solvent anneal is conducted by exposing a block copolymer film to a saturated solvent atmosphere at 25° C. for at least 12 hours (and often longer).

Accordingly, what are needed are new apparatus and new methods for performing solvent vapor-assisted annealing of block copolymers.

### SUMMARY OF THE INVENTION

The present invention overcomes the foregoing problems and other shortcomings, drawbacks, and challenges of conventional solvent anneal process of directed self-assembly applications. While the invention will be described in connection with certain embodiments, it will be understood that the invention is not limited to these embodiments. To the contrary, this invention includes all alternatives, modifications, and equivalents as may be included within the scope of the present invention.

According to an embodiment of the present invention, a method for annealing a layered substrate comprising a layer of a block copolymer is provided. The method comprises (a) introducing an annealing gas into a processing chamber containing the layered substrate in a sufficient quantity to provide a processing pressure (P), wherein the annealing gas comprises a gaseous solvent present at a partial pressure (Pₛₒₗ) in an amount less than about 100 torr, or in an amount less than a saturation pressure of the gaseous solvent; (b) maintaining the annealing gas in the processing chamber for a first time period to permit at least a portion of the annealing gas to absorb into the layer of the block copolymer; (c) removing the annealing gas from the processing chamber to provide an environment within the processing chamber for a second time period, wherein the environment is either at least less than about 90% P or at least less than about 90% Pₛₒₗ to facilitate an evaporation of the gaseous solvent from the layer of the block copolymer; and (d) repeating steps (a)-(c) a plurality of times in order induce the block copolymer to undergo cyclic self-assembly.

In accordance with another embodiment of the present invention, a solvent annealing apparatus useful for solvent-assisted annealing of a layer of a block copolymer is provided. The apparatus includes a processing chamber comprising a process space; a substrate support in the process space, the substrate support having a support surface and being configured to support the substrate in the process space in a spaced relationship with the support surface to define a processing environment between the support surface and the substrate; an annealing gas supply in fluid communication with the process space, the anneal gas supply configured to supply an annealing gas to the process space; a heating element positioned within the processing chamber configured to heat the substrate by heat transfer through the processing environment or the substrate support; an exhaust port in the processing chamber configured in fluid communication with an isolation valve; a purge gas supply in fluid communication with the process space, the purge gas supply configured to supply a purge gas to the process space effective to displace the annealing gas from the process space; and a sequencing device electrically coupled to the annealing gas supply, the heating element, the isolation valve of the exhaust port, and the purge gas supply. The sequencing device is programmed to control the annealing gas supply, the heating element, the isolation valve of the exhaust port, and the purge gas supply.

The above and other objects and advantages of the present invention shall be made apparent from the accompanying drawings and the descriptions thereof.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a flow chart illustrating a method of solvent gas-assisted annealing of a layered substrate comprising a layer of a block copolymer, in accordance with an embodiment of the present invention;

FIG. 2 is a cross-sectional view of a solvent annealing apparatus for use in block copolymer annealing processes, in accordance with embodiments of the present invention; and

FIGS. 3A-3H illustrate a lithographic patterning and directed self-assembly technique implementing the method illustrated in FIG. 1.

### DETAILED DESCRIPTION

Apparatus and methods for solvent-assisted annealing of a substrate with direct self-assembly (“DSA”) integration are disclosed in various embodiments. However, one skilled in the relevant art will recognize that the various embodiments may be practiced without one or more of the specific details or with other replacement and/or additional methods, materials, or components. In other instances, well-known structures, materials, or operations are not shown or described in detail to avoid obscuring aspects of various embodiments of the present invention.

Similarly, for purposes of explanation, specific numbers, materials, and configurations are set forth in order to provide a thorough understanding. Nevertheless, the embodiments of the present invention may be practiced without specific details. Furthermore, it is understood that the illustrative representations are not necessarily drawn to scale.

Reference throughout this specification to “one embodiment” or “an embodiment” or variation thereof means that a particular feature, structure, material, or characteristic described in connection with the embodiment is included in at least one embodiment of the invention, but does not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Additionally, it is to be understood that “a” or “an” may mean “one or more” unless explicitly stated otherwise.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment.

Various additional operations may be performed and/or described operations may be omitted in additional embodiments.

In accordance with embodiments of the present invention and in reference to the flow chart of FIG. 1, a method for annealing a layered substrate comprising a layer of a block copolymer is provided. The method 10 comprises introducing a solvent annealing gas into a processing chamber containing the layered substrate in 20; maintaining the solvent annealing gas in the processing chamber for a first time period in 30; removing the solvent annealing gas from the processing chamber for a second time period in 40; and repeating steps 20-40 a plurality of times to induce the block copolymer to undergo cyclic self-assembly in 50. The method 10 can be performed as the principal annealing step of a directed self-assembly lithographic process, or used as a supplemental processing step subsequent to a more traditional annealing treatment, such as thermal anneal, to finely control the self-assembly of the block copolymer.

Without being bound by any particular theory, it is believed that the layer of block copolymers absorb gaseous organic solvents in one or both phases of the block copolymer, which can facilitate microphase separation of the block copolymer. The absorption of the solvent causes the film to swell, which is believed to provide spatial freedom for the respective polymer blocks to organize into domains.

In traditional solvent annealing, the layer of the block copolymer is exposed to a solvent vapor that absorbs into the layer and acts to plasticize the block copolymer. The presence of solvent molecules with the copolymer matrix creates space between the polymer block chains thereby increasing chain mobility. It is this solvent-permitted mobility that facilitates the self-assembly of block polymers into discrete domains. However, if the solvent concentration in the film becomes too high, the polymer film will take on properties of a solvated polymer and will de-wet from the substrate. Therefore, the block copolymer/solvent system of interest provides a natural upper bound for the useful partial pressure of the solvent. However, by using cycles of solvent annealing, higher partial pressures of the annealing gas may be used because the absorbed solvent does not have enough time to equilibrate with the block copolymer to induce de-wetting. The block copolymer sees short time cycles of heightened mobility, but then loses that heightened mobility as the solvent is removed. The subsequent cycle will add another period of high mobility during which the polymer may further self-assemble. By controlling the pressure of the solvent, the temperature, and the relative time steps, the progression of the self-assembly process can be controlled.

One area where this technique may be of particular interest is in a scheme where an initial anneal (perhaps e.g., a thermal anneal) has already aligned the polymer, but has left a high concentration of defects. Literature proposes that these These defects have formed because they have been trapped in a local free energy well and have not been able to continue on to their lowest free energy state (Fredrickson reference). The use of the cycled solvent anneal at high partial pressures can allow for heightened mobility for short periods of time and allow for the imperfectly-aligned block copolymer to overcome its confinement in its previous free energy well and then proceed to its lowest possible free energy state, the one that is defect free.

As used herein, the term “polymer block” means and includes a grouping of multiple monomer units of a single type (i.e., a homopolymer block) or multiple types (i.e., a copolymer block) of constitutional units into a continuous polymer chain of some length that forms part of a larger polymer of an even greater length and exhibits a χN value, with other polymer blocks of unlike monomer types, that is sufficient for phase separation to occur. χ is the Flory-Huggins interaction parameter and N is the total degree of polymerization for the block copolymer. According to embodiments of the present invention, the χN value of one polymer block with at least one other polymer block in the larger polymer may be equal to or greater than about 10.5.

As used herein, the term “block copolymer” means and includes a polymer composed of chains where each chain contains two or more polymer blocks as defined above and at least two of the blocks are of sufficient segregation strength (e.g. χN>10.5) for those blocks to phase separate. A wide variety of block polymers are contemplated herein including diblock copolymers (i.e., polymers including two polymer blocks (AB)), triblock copolymers (i.e., polymers including three polymer blocks (ABA or ABC)), multiblock copolymers (i.e., polymers including more than three polymer blocks (ABCD, etc.)), and combinations thereof.

As used herein, the term “substrate” means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The terms “microphase segregation” and “microphase separation,” as used herein mean and include the properties by which homogeneous blocks of a block copolymer aggregate mutually, and heterogeneous blocks separate into distinct domains. In the bulk, block copolymers can self assemble into ordered morphologies, having spherical, cylindrical, lamellar, or bicontinuous gyroid microdomains, where the molecular weight of the block copolymer dictates the sizes of the microdomains formed. The domain size or pitch period (L_{O}) of the self-assembled block copolymer morphology may be used as a basis for designing critical dimensions of the patterned structure. Similarly, the structure period (L_{S}), which is the dimension of the feature remaining after selectively etching away one of the polymer blocks of the block copolymer, may be used as a basis for designing critical dimensions of the patterned structure.

The lengths of each of the polymer blocks making up the block copolymer may be an intrinsic limit to the sizes of domains formed by the polymer blocks of those block copolymers. For example, each of the polymer blocks may be chosen with a length that facilitates self-assembly into a desired pattern of domains, and shorter and/or longer copolymers may not self-assemble as desired.

The term “annealing” or “anneal” as used herein means and includes treatment of the block copolymer so as to enable sufficient microphase segregation between the two or more different polymeric block components of the block copolymer to form an ordered pattern defined by repeating structural units formed from the polymer blocks. Annealing of the block copolymer in the present invention is premised on a solvent vapor-assisted annealing (either at or above room temperature), but may be used in conjunction with other annealing techniques, such thermal annealing (either in a vacuum or in an inert atmosphere, such as nitrogen or argon), or supercritical fluid-assisted annealing. Other conventional annealing methods not described herein may also be utilized. As a specific example of a combination of anneal processes, a thermal annealing of the block copolymer may be conducted first by exposing the block copolymer to an elevated temperature that is above the order-disorder temperature (ODT), but below the degradation temperature (T_{d}) of the block copolymer, which is then followed by the solvent vapor-assisted annealing processes described herein.

The term “preferential wetting,” as used herein, means and includes wetting of a contacting surface by a block copolymer wherein one polymer block of the block copolymer will wet a contacting surface at an interface with lower free energy than the other block(s). For example, preferential wetting may be achieved or enhanced by treating the contacting surface with a material that attracts a first polymer block and/or repels a second polymer block of the block copolymer.

The ability of block copolymers to self-organize may be used to form mask patterns. Block copolymers are formed of two or more chemically distinct blocks. For example, each block may be formed of a different monomer. The blocks are immiscible or thermodynamically incompatible, e.g., one block may be polar and the other may be non-polar. Due to thermodynamic effects, the copolymers will self-organize in solution to minimize the energy of the system as a whole; typically, this causes the copolymers to move relative to one another, e.g., so that like blocks aggregate together, thereby forming alternating regions containing each block type or species. For example, if the copolymers are formed of polar (e.g. organometallic-containing polymers) and non-polar blocks (e.g., hydrocarbon polymers), the blocks will segregate so that non-polar blocks aggregate with other non-polar blocks and polar blocks aggregate with other polar blocks. It will be appreciated that the block copolymers may be described as a self-assembling material since the blocks can move to form a pattern without active application of an external force to direct the movement of particular individual molecules, although heat may be applied to increase the rate of movement of the population of molecules as a whole.

In addition to interactions between the polymer block species, the self-assembly of block copolymers can be influenced by topographical features, such as steps or guides extending perpendicularly from the horizontal surface on which the block copolymers are deposited. For example, a diblock copolymer, a copolymer formed of two different polymer block species, may form alternating domains, or regions, which are each formed of a substantially different polymer block species. When self-assembly of polymer block species occurs in the area between the perpendicular walls of a step or guides, the steps or guides may interact with the polymer blocks such that, e.g., each of the alternating regions formed by the blocks is made to form a regularly spaced apart pattern with features oriented generally parallel to the walls and the horizontal surface.

Such self-assembly can be useful in forming masks for patterning features during semiconductor fabrication processes. For example, one of the alternating domains may be removed, thereby leaving the material forming the other region to function as a mask. The mask may be used to pattern features such as electrical devices in an underlying semiconductor substrate. Methods for forming a copolymer mask are disclosed in U.S. Pat. No. 7,579,278; and U.S. Pat. No. 7,723,009, the entire disclosure of each of which is incorporated by reference herein.

Exemplary organic polymers include, but are not limited to, poly(9,9-bis(6′-N,N,N-trimethylammonium)-hexyl)-fluorene phenylene) (PFP), poly(4-vinylpyridine) (4PVP), hydroxypropyl methylcellulose (HPMC), polyethylene glycol (PEG), poly(ethylene oxide)-co-poly(propylene oxide) di- or multiblock copolymers, poly(vinyl alcohol) (PVA), poly(ethylene-co-vinyl alcohol) (PEVA), poly(acrylic acid) (PAA), polylactic acid (PLA), poly(ethyloxazoline), a poly(alkylacrylate), polyacrylamide, a poly(N-alkylacrylamide), a poly(N,N-dialkylacrylamide), poly(propylene glycol) (PPG), poly(propylene oxide) (PPO), partially or fully hydrolyzed poly(vinyl alcohol), dextran, polystyrene (PS), polyethylene (PE), polypropylene (PP), polyisoprene (PI), polychloroprene (CR), a polyvinyl ether (PVE), poly(vinyl acetate) (PV_{Ac}), poly(vinyl chloride) (PVC), a polyurethane (PU), a polyacrylate, polymethacrylate, an oligosaccharide, or a polysaccharide.

Exemplary organometallic-containing polymers include, but are not limited to, silicon-containing polymers such as polydimethylsiloxane (PDMS), polyhedral oligomeric silsesquioxane (POSS), or poly(trimethylsilylstyrene (PTMSS), or silicon- and iron-containing polymers such as poly(ferrocenyldimethylsilane) (PFS).

Exemplary block copolymers include, but are not limited to, diblock copolymers such as polystyrene-b-polydimethylsiloxane (PS-PDMS), poly(2-vinylpyridine)-b-polydimethylsiloxane (P2VP-PDMS), polystyrene-b-poly(ferrocenyldimethylsilane) (PS-PFS), or polystyrene-b-poly-DL-lactic acid (PS-PLA), or triblock copolymers such as polystyrene-b-poly(ferrocenyldimethylsilane)-b-poly(2-vinylpyridine) (PS-PFS-P2VP), polyisoprene-b-polystyrene-b-poly(ferrocenyldimethylsilane) (PI-PS-PFS), or polystyrene-b-poly(trimethylsilylstyrene)-b-polystyrene (PS-PTMSS-PS). In one embodiment, a PS-PTMSS-PS block copolymer comprises a poly(trimethylsilylstyrene) polymer block that is formed of two chains of PTMSS connected by a linker comprising four styrene units. Modifications of the block copolymers is also envisaged, such as that disclosed in U.S. Patent Application Publication No. 2012/0046415, the entire disclosure of which is incorporated by reference herein.

Several aspects of the present invention can affect the efficiency of the solvent vapor-assisted annealing process. These aspects include a chemical nature of the organic solvent(s) selected for the solvent annealing gas with respect to the subject block copolymer; a degree of swelling in the layer of the block copolymer; a partial pressure (Pₛₒₗ) of the organic solvent in the solvent annealing gas; a processing temperature of the processing chamber; a processing pressure in the processing chamber; a first time period of exposing the layer of the block copolymer to the solvent annealing gas; a second time period where the layer of the block copolymer is not being exposed to the solvent annealing gas; and a number of cycles between the first period and the second period. Each of these will be discuss below.

The chemical nature of the organic solvent(s) with respect to the subject block copolymer is either a selective or a non-selective (or neutral) solvent. A selective solvent is one that prefers one of the block of the block copolymer over the other(s). In the case of a triblock or higher order block copolymer, a selective solvent may prefer two or more blocks over another block. A neutral solvent is a solvent in which all blocks of the block copolymer have good solubility.

The choice of solvent can affect the maximum solvent volume fraction, morphology, and domain size of the assembled film. Phases of block copolymer/solvent systems can depend on the volume fraction of the solvent as well as the temperature and relative volume fractions of the blocks. For example, the morphology of a symmetric diblock copolymer annealed in a selective solvent at low temperature may change from lamellae, gyroid, cylinder, sphere, and micelles upon increase of solvent fraction.

Solvents may be generally organic in nature. Common organic solvents useful for solvent vapor-assisted annealing include, but are not limited to, acetone, chloroform, butanone, toluene, diacetone alcohol, heptanes, tetrahydrofuran, dimethylformamide, carbon disulfide, or combinations thereof. For polymer blocks that contain silicon in them, solvents containing silicon will generally more readily absorb into the film. Hexamethyl-disilizane, dimethylsilyl-dimethylamine, pentamethyldisilyl-dimethyl amine, and other such silylating agents having high vapor pressures may be used in embodiments of the present invention. Moreover, solvent mixtures may also be used, the solvent mixture comprising at least one solvent compatible with each copolymer to ensure proper copolymer swelling to increase polymer mobility.

The amount of solvent incorporation during exposure to the solvent vapor can be tracked in situ by measuring film swelling using a number of optical spectroscopy techniques, such as optical reflectometry. Swelling ratio is the ratio of the solvent-containing film thickness to the pure film thickness, with the solvent volume fraction determined from the swelling ratio. The solvent volume fraction of a particular block copolymer at a particular temperature determines the morphology of the block copolymer. Depending on the nature of the solvent molecules, the swelling ratio of each block and the relative volume fraction may be greatly different, which may lead to different morphologies.

The degree of swelling can be controlled by several factors, such as the partial pressure (Pₛₒₗ) of the organic solvent vapor, the flow rate of the organic solvent vapor, the exposure time, etc.

The partial pressure (Pₛₒₗ) of the organic solvent in the solvent annealing gas affects the amount of solvent available for absorption into the layer of the block copolymer. Accordingly, the higher the Pₛₒₗ, the higher the effective concentration of the solvent in the solvent annealing gas. It should be appreciated that Pₛₒₗ is a function of the amount of solvent introduced into the processing chamber up to the saturation level at a given processing temperature. According to an embodiment, the Pₛₒₗ of the solvent in the process chamber is less than 100 torr.

Accordingly, the processing temperature in the processing chamber is an important in this regard. Increasing temperature in the processing chamber increases the amount of organic solvent vapor that can be dissolve in the solvent annealing gas used in the processing chamber, i.e., increases the level at which saturation is reached. According to an embodiment, the processing temperature is less than 100° C., for example, from about room temperature to about 70° C.

The temperature can be controlled in a process chamber by many different types of heating elements. For example, an absorption-based heating element or a conduction-based heating element can be present in the processing chamber.

The processing pressure in the processing chamber can affect the rate at which the solvent is adsorbed. Accordingly, an initial high operating pressure may accelerate the time to reach full solvent penetration through the layer of the block copolymer. But after some time frame, the processing pressure may be decreased to better control the anneal.

The first time period of exposing the layer of the block copolymer to the solvent annealing gas, the second time period where the layer of the block copolymer is not being exposed to the solvent annealing gas, and the number of cycles between the first period and the second period all affect the throughput of substrates through the solvent gas-assisted anneal. Moreover, each of the foregoing can be adjusted as necessary to accommodate for the foregoing aspects relating to temperatures and pressures. According to an embodiment, the first and second time period may be in a range from about 1 second to about 60 seconds. For example, the first and/or the second time period may be from about 2 seconds to about 15 seconds. The number of cycles between the first and second time periods is not particularly limited. For example, in one embodiment, the cycle of steps was repeated 20-50 at 15 seconds of solvent exposure followed by a 15 second exposure without solvent.

Turning now to FIG. 2, a solvent annealing apparatus 100, which is suitable for performing the cyclic solvent vapor-assisted annealing of block copolymers in accordance with embodiments of the present invention, includes a processing chamber 112 with a base 130 having a sidewall 118 and a shielding plate 120 intersecting the sidewall 118, and a lid 122. The lid 122 and base 130 collectively define the process chamber 112, when the lid 122 is sealed with the base 130 that encloses a process space 126 containing a gaseous environment. The solvent annealing apparatus 110 is adapted to treat a layered substrate 130 comprising a layer 132 of the block copolymer to assist the block copolymer to self-assemble into a plurality of domains. Additionally, the solvent annealing apparatus 100 is adapted to heat the layered substrate 130 process temperatures above room temperature and up to about 100° C. by pressurizing the gaseous environment to which the layered substrates 130 are exposed inside the process space 126, or through radiative, conductive, convective, or combinations thereof.

Disposed in the processing chamber 112 is a support surface 134 with passageways 138. Lift pins 140 are disposed in and aligned with the passageways 138. The lift pins 140 are moveable between a first lowered position, where the pins are flush or below an upper surface of the support surface 134 to a second lifted position where the lift pins project above the upper surface of the support surface 134. The lift pins 140 are connected to and supported by a lift pin arm 144, which is further connected to and supported by a rod 148 of a hydraulic cylinder 112. When the rod 148 is actuated to extend from the hydraulic cylinder 150, the lift pins 140 project beyond the support surface 134, thereby lifting the layered substrate 130 above the support surface 134.

The lid 122 is moveable from a first open position in which the lid 122 is separated from the base 130 to a second closed position where lid 122 extends down to meet the sidewall 118 and the base 130 creating an enclosed volume. A sealing member have the representative form of an O-ring 154 is positioned on either the sidewall 118 or the lid 122 and may assist in sealing the processing chamber 112 when the lid 122 is in the second closed position. While an O-ring 154 is utilized in this embodiment, any number of sealing components may be used at the interface between the lid 122 and the sidewall 118 as long as the seal is sufficient to withstand pressurization and/or evacuation of the processing chamber 112 to the operating pressures and temperatures. Further, the O-ring 154 should be compatible with an annealing gas atmosphere or environment inside the process space 126 to a temperature sufficient to permit heating of the layered substrate 130 and a layer 132 of the block copolymer to process temperatures. When the lid 122 is in the first open position, layered substrate 130 may be loaded into and unloaded from the processing chamber 112. For example, the layered substrate 130 may be unloaded from the processing chamber 112 after termination of the solvent-assisted annealing of the layer 132, or to transfer the layered substrate to a cooling chamber (not shown) or to a buffer (not shown). The loading and unloading is permitted through the gaps 158a, 158b.

Referring further to FIG. 2, when the layered substrate 130 is positioned on the support surface 134, the lid 122 is lowered to the second closed position to make contact with the sidewall 118 and the base 114. The lid 122 is held in contact with the sidewall 118 and the base 114 by a locking mechanism 164, which seals the processing chamber 112. The locking mechanism 164 may be a mechanical locking device as illustrated in this embodiment, or in an alternate embodiment, the locking mechanism may be a vacuum system that draws the lid 122 down to the sidewall 118 and the base 114 and then maintains the contact with the vacuum lock during the pressurization of the gaseous environment in the process space 126 inside the processing chamber 112. In still other embodiments, the locking mechanism 164 may employ both the vacuum system to draw the lid 122 down and a mechanical locking device to maintain contact when the processing chamber 112 is pressurized.

A solvent anneal gas supply 170, which is fluidly coupled with a gas inlet port 174 through a solvent anneal gas inlet valve 180, may be used to introduce a gas, as diagrammatically indicated by single headed arrow number 176, into the processing chamber 112. The solvent annealing gas introduced through the gas inlet port 174 in the lid 122 operates to provide a measured quantity of the solvent anneal gas to the process space 126. In a further aspect, the anneal gas inlet valve 176 and gas inlet port 174, as well as any other lines or equipment that may come in contact with the solvent anneal gas, may be heated to maintain the anneal gas (i.e., organic solvent vapor) in its vapor form prior to introducing the annealing gas into the process space 126.

The gas inlet port 174 is further fluidly coupled to a purge gas supply 178, which is isolated from the gas inlet port 174 by a purge gas supply valve 180. Accordingly, the operation of the purge gas supply valve 180 and the anneal gas inlet valve 176 can be coordinated as such that while one of the two is open and supplying its gas to the processing chamber 126, the other is closed.

The solvent annealing apparatus 100 further comprises an exhaust port 190 in fluid communication with compartment 202, which is further in fluid communication with the process space 126 via small exhaust ports 186 transversing the support surface 134. Accordingly, evacuation of the process space 126 is accomplished by operation of a vacuum pump 198, which is isolated from the exhaust port 190 by an exhaust port valve 194. Simultaneous supply of the purge gas while evacuating can serve to flush the process space 126 of the residual solvent annealing gas by operation of the vacuum pump with the purge gas supply valve 180 and the exhaust port valve 194 open.

The solvent annealing apparatus 100 further includes an optical device 210, which can be used to measure the swelling and/or shrinking of the layer 132 of the block copolymer during the solvent vapor-assisted annealing process. The solvent annealing apparatus 100 further includes heating elements 220, which serve to heat the process space 126 and/or the layer 132 of the block copolymer. Additionally, the operation of the solvent annealing apparatus 100 can be controlled by a sequencing device 216. The sequencing device 216 is electrolytically-coupled to the solvent anneal gas supply valve 175, the purge gas supply valve 180, the exhaust port valve 194, the optical device 210, and the heating elements 220, and is programmed to control the same.

According to embodiments of the present invention, the layered substrate 130 comprises the layer 132 of the block copolymer. The layer 132 is exposed to and contacted by the annealing gas by opening of the anneal gas inlet valve 176, which permits the solvent anneal gas to enter the process space 126. The solvent anneal gas may be continuously supplied to the process space 126 with or without the exhaust port valve 194 in its open position. When the exhaust port valve 194 is open, venting occurs simultaneously with a continuous supply of annealing through the inlet port 174 in the processing chamber 112 at an introduction rate that maintains the pressure of the gaseous environment inside process space 126 substantially constant. Alternatively, the solvent anneal gas inlet valve 176 may be opened for a predetermined length of time to permit a defined quantity of the solvent anneal gas to enter the process space 126 while the exhaust port valve 194 is closed to provide a static treatment environment. To maintain the solvent anneal gas in its vapor phase, the partial pressure (Pₛₒₗ) of the solvent in the solvent anneal gas should be kept below its saturation point at the processing pressure (P) and temperature. For example, in one embodiment, the partial pressure (Pₛₒₗ) of the solvent in the process space is less than 100 torr.

The annealing gas can be permitted to absorb into the layer 132 of the block copolymer for the desired length of time (a first time period). If desired, the first time period can be correlated to a predetermined swell ratio value, which can be measured by the optical device 210.

For the continuous flow operation, to remove the solvent annealing gas from the process space 126, the anneal gas inlet valve 176 is closed, while the exhaust port valve 194 remains open. To expedite the elimination of the annealing gas from the process space 126, the purge gas supply valve 180 can be opened to enable the flushing of the process space 126 with the purge gas. For the static treatment environment, opening the exhaust port valve 194 permits the vacuum pump 198 to withdraw the solvent annealing gas, which may be accompanied by flushing with the purge gas as described above, if desired. In either case, the partial pressure (Pₛₒₗ) of any residual solvent annealing gas should be minimized, for example, at least less than about 90% Pₛₒₗ of the first time period in order to facilitate an evaporation of the gaseous solvent from the layer of the block copolymer.

The layer 132 of the block copolymer is next aged for the desired length of time (a second time period) to permit the solvent that had dissolved into the layer 132 to evaporate therefrom. To assist the evaporation of the solvent, the pressure of the process space can be lowered to below the process pressure present at the time of the solvent annealing gas treatment. For example, the pressure can be reduced to an amount less than 90% of the processing pressure (P).

As discussed above, the process of absorbing and evaporating the solvent anneal gas into and out of the layer 132 of the block copolymer is accomplished by repeating the process described above to provide a cyclic self-assembly of the block copolymer. The solvent vapor-assisted annealing process described herein can be controlled by a sequencing device 216 based on a preset number of cycles or empirically-derived.

Implementation of the solvent gas-assisted anneal in accordance with embodiments of the present invention is discussed next. With reference to FIGS. 3A-3H, a cross-sectional side view of a layered structure 300 is illustrated having a substrate 310 with an overlying developed photoimageable layer 312 after having removed portions of the photoimageable layer 312 to provide spaces 314 and leaving unremoved portions or features 318. Unremoved portions or features 318 in the photoimageable layer 312 may be formed using standard photolithographic techniques that are commonly used in the art.

With reference to FIG. 3B, a layer 330 of an inorganic material having a thickness C is blanket deposited conformally over exposed surfaces, including the unremoved portions 318 of the photoimageable layer 312, and the underlying substrate 310.

With continued reference to FIGS. 3B and 3C, the layer 330 of the inorganic material is then subjected to an anisotropic etch to remove material from horizontal surfaces 350 of the layered structure 301. After completing the anisotropic etch, which exposes the unremoved portions 318 of the photoimageable layer 312, of the layer 330 from the horizontal surfaces 350, the unremoved portions 318 are removed to provide a plurality of spaced apart inorganic material guides 340. The inorganic material guides 340 serve as mandrels for the casting of a layer of the block copolymer, and serve to improve registration of the self-assembled block copolymer cylindrical domains.

With reference to FIG. 3D, a film 360 of a surface modifying material is deposited between and over the plurality of spaced apart inorganic materials guides 340. The surface modifying material serves to attract one of the polymer blocks and/or repel another polymer block of the block copolymer, and permits or enhances preferential wetting. With reference to FIG. 3E, a layer of the block copolymer 370 is applied and subsequently annealed to induce self-assembly to form a mask pattern over the substrate 310.

With reference to FIGS. 3E and 3F, the layer of block copolymer 370 is exposed to annealing conditions to facilitate the self-assembly of the block copolymer into a plurality of cylindrical features 382, which, in this example, are generally parallel to each other, the horizontal surface of the substrate 350, and vertical surfaces 388 of the inorganic material guides 340. The self-organization may be facilitated and accelerated by annealing the layered structure 300, as discussed next.

Treating the layered substrate 304 in the solvent anneal apparatus 100 to a solvent gas-assisted anneal provides a layered substrate 305 having a layer of self-assembled block copolymer 380 having domains 282, 284. In an alternative embodiment, the solvent gas-assisted anneal may be preceded by other conventional annealing treatments, such as a thermal anneal.

In the embodiment shown, the domain period (L_{O}) of the cylindrical features 382 is approximately a fifth of the critical dimensions A and E, and the structure periodicity (L_{S}) of the cylindrical features 382 is approximately a tenth of the critical dimensions A and E, which thereby facilitates the formation of four parallel cylindrical features 382, thereby providing frequency multiplication.

With reference to FIGS. 3F and 3G, the annealing treatment of the layer of block copolymer 370 provides a layer of self-assembled block polymer having cylindrical features 382, which are formed of the second polymer block, and surrounding regions 384, which are formed of the first block polymer. At least a portion of the surrounding regions 384 is selectively removed, leaving behind the etched cylindrical features 386, small sections of surrounding regions 384, and the inorganic material guides 340, as shown in FIG. 3G. It will be appreciated that portions of the surrounding regions 384 may be removed in a single step using a single etch chemistry or may be removed using multiple etches with different etch chemistries to provide a pattern 390.

With reference to FIG. 3H, the pattern 390 of FIG. 3G is transferred to the substrate 310 to provide a transferred pattern 395. The pattern transfer may be accomplished using etch chemistries appropriate for selectively etching the material or materials of the substrate 310 relative to the inorganic material guides 340 and the etched cylindrical features 386.

While the present invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method and illustrative examples shown and described. Accordingly, departures may be made from such details without departing from the scope of the general inventive concept.

What is claimed is:

1. A method for annealing a layered substrate comprising a layer of a block copolymer, comprising:
(a) introducing an annealing gas into a processing chamber containing the layered substrate in a sufficient quantity to provide a processing pressure (P), wherein the annealing gas comprises a gaseous solvent present at a partial pressure (Pₛₒₗ) in an amount less than about 100 torr, or in an amount less than a saturation pressure of the gaseous solvent;
(b) maintaining the annealing gas in the processing chamber for a first time period to permit at least a portion of the annealing gas to absorb into the layer of the block copolymer;
(c) removing the annealing gas from the processing chamber to provide an environment within the processing chamber for a second time period, wherein the environment is either at least less than about 90% processing pressure (P) or at least less than about 90% Pₛₒₗ to facilitate an evaporation of the gaseous solvent from the layer of the block copolymer; and
(d) repeating steps (a)-(c) a plurality of times to induce the block copolymer to undergo cyclic self-assembly.

2. The method of claim 1, wherein the gaseous solvent is selected from a neutral solvent or a selective solvent.

3. The method of claim 1, wherein the gaseous solvent is comprises an organic solvent.

4. The method of claim 1, further comprising:
(e) controlling a processing temperature of the processing chamber, wherein the processing temperature is within a range from about room temperature to about 100° C.

5. The method of claim 4, wherein the processing chamber further comprises a heating element selected from an absorption-based heating element, a conduction-based heating element, or a combination thereof; wherein the controlling the processing temperature comprises modulating an operation of the heating element.

6. The method of claim 1, wherein the maintaining the annealing gas in the processing chamber for the first time period causes the layer of the block copolymer to swell, the method further comprising:
(f) measuring swelling of the film layer to provide a swelling ratio measurement.

7. The method of claim 6, further comprising;
adjusting a duration of the first time period, a duration of the second time period, a number of time the steps (a)-(c) are repeated, or combinations thereof in response to the swelling ratio measurement.

8. The method of claim 1, wherein introducing the annealing gas into the processing chamber is a pulsing of a measured quantity of the annealing gas.

9. The method of claim 1, wherein removing the annealing gas from the processing chamber comprises purging the process chamber with an inert purge gas, evacuating the processing chamber, or a combination thereof.

10. The method of claim 1, wherein removing the annealing gas from the processing chamber comprises:
venting a first amount of the annealing gas to a location outside of the processing chamber to remove the annealing gas therefrom; and
introducing a purge gas into the processing chamber, while venting, at an introduction rate sufficient to replace the first amount.

11. The method of claim 1, wherein a duration of the first period is in a range from about 1 second to about 60 seconds, and wherein a duration of the second period is in a range from about 1 second to about 60 seconds.

12. The method of claim 1, wherein a number of times the steps of (a)-(c) are repeated is determined by a processing temperature, the processing pressure (P), the partial pressure (Pₛₒₗ), a duration of the first period, a duration of the second period, or combinations thereof.

13. The method of claim 1, further comprising:
(f) thermally quenching the layered substrate to a quenching temperature at a rate of greater than about 50° C./minute.

14. The method of claim 1, further comprising performing a non-solvent anneal or a traditional solvent anneal prior to performing steps (a)-(d).

15. A layered substrate comprising a layer of a self-assembled block copolymer provided by the method of claim 1.

16. A solvent annealing apparatus for a solvent-assisted annealing of a layer of a block copolymer, comprising:
a processing chamber comprising a process space;
a substrate support in the process space, the substrate support having a support surface and being configured to support the substrate in the process space in a spaced relationship with the support surface to define a processing environment between the support surface and the substrate;
an annealing gas supply in fluid communication with the process space, the anneal gas supply configured to supply an annealing gas to the process space;
a heating element positioned within the processing chamber configured to heat the substrate by heat transfer through the processing environment or the substrate support;
an exhaust port in the processing chamber configured in fluid communication with an isolation valve;
a purge gas supply in fluid communication with the process space, the purge gas supply configured to supply a purge gas to the process space effective to displace the annealing gas from the process space; and
a sequencing device electrically coupled to the annealing gas supply, the heating element, the isolation valve of the exhaust port, and the purge gas supply, wherein the sequencing device is programmed to control the annealing gas supply, the heating element, the isolation valve of the exhaust port, and the purge gas supply.

17. The solvent annealing apparatus of claim 15, further comprising:
an optical device disposed within the processed space and arranged relative to the support surface to permit a direct line of light transmission to a front surface of the substrate, the optical device adapted to measure swelling of a film layer deposited the front layer of the substrate.

18. The solvent annealing apparatus of claim 17, wherein the sequencing device is electrically couple to the optical device and programmed to control the annealing gas supply, the heating element, the isolation valve of the exhaust port, and the purge gas in response to a measurement of swelling of the film layer.

19. The solvent annealing apparatus of claim 15, further comprising:
a vacuum pump fluidly coupled with the exhaust port for evacuating the process space.

20. The solvent annealing apparatus of claim 15, further comprising
a thermal quenching gas supply in fluid communication with the process space, the quenching gas supply configure to supply a thermal quenching gas to the process space effective to reduce a temperature of the process space greater than 50° C. within about 1 second or less.
